(19) United States
(12) Patent Application Publication
(10) Pub. No.: US 2026/0214917 A1
(43) Pub. Date: Jul. 23, 2026

(54) METHOD OF FORMING A METAL-INSULATOR-METAL CAPACITOR INCLUDING A DIELECTRIC MATERIAL FILM

(71) Applicant: ASM IP Holding B.V., Almere (NL)

(72) Inventors: Jessica Akemi Cimada da Silva, Chandler, AZ (US); Rohit Abraham John, Chandler, AZ (US); Fu Tang, Gilbert, AZ (US); Mihaela Balseanu, Scottsdale, AZ (US); Gyunghyun Ryu, Chandler, AZ (US); Alessandra Leonhardt, Sipoo (FI)

(21) Appl. No.: 19/450,949

(22) Filed: Jan. 16, 2026

Related U.S. Application Data
(60) Provisional application No. 63/747,455, filed on Jan. 21, 2025.

(51) Int. Cl. H10D 1/00; H10D 1/68

(52) U.S. Cl. CPC H10D 1/041; H10D 1/684

(57) ABSTRACT

A method for forming a MIM capacitor includes providing a substrate, optionally forming a first conductive material, forming a dielectric material, optionally forming a second dielectric material, and microwave annealing the dielectric material.

### CROSS-REFERENCE TO RELATED APPLICATIONS

This application is a nonprovisional of, and claims priority to and the benefit of, U.S. Provisional Patent Application No. 63/747,455 , filed Jan. 21, 2025 and entitled “METHOD OF FORMING A METAL-INSULATOR-METAL CAPACITOR INCLUDING A DIELECTRIC MATERIAL FILM,” which is hereby incorporated by reference herein.

### FIELD

Examples are described that relate to a method for forming a metal-insulator-metal (MIM) capacitor that includes a dielectric material film of the MIM capacitor, as well as to a structure comprising a MIM capacitor and a substrate processing apparatus for forming a MIM capacitor using a microwave treatment of a dielectric material film.

### BACKGROUND

The scaling of semiconductor devices has led to significant improvements in speed and density of integrated circuits. The scaling of semiconductor devices has presented challenges in the fabrication of metal-insulator-metal (MIM) devices that include high dielectric constant (high-k) materials.

High-k materials may exhibit desirable electrical properties for the functionality of MIM devices. However, the formation of high-k materials with increasingly smaller thicknesses in increasingly smaller MIM devices has been met with challenges. MIM devices may need to be formed and/or annealed with reduced thermal budgets. Additionally, conventional techniques for making high purity high-k materials may be time-intensive, expensive, and complex. Thus, there exists a need for improved methods of forming MIM capacitors and dielectric materials that maintain desirable properties and that can be formed with a relatively low thermal budget.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Examples described herein provide a substrate processing method, substrate processing apparatus, and a structure on a substrate. Various examples of the substrate processing method provide for the formation of a dielectric film for a MIM capacitor comprising the dielectric film, or other semiconductors devices comprising a dielectric material film. The methods disclosed herein provide dielectric material films with desired properties, such as thicknesses below 100 Angstroms, which are performed at substrate temperatures at or below 400° C.

According to one or more embodiments, a method of forming a metal-insulator-metal (MIM) capacitor, which includes forming a dielectric material, is provided. An exemplary method includes providing a substrate in a reaction chamber comprising a reaction space. In some embodiments, the provided substrate comprises a first conductive material film on a surface of the substrate. In some embodiments, the method includes forming a first conductive material. An exemplary method continues with forming a dielectric material film. In some embodiments, the method includes forming a second conductive material. In some embodiments, the method continues with performing a microwave treatment.

In some embodiments, forming a first conductive material comprises a physical vapor deposition (PVD) process. In other embodiments, forming a first conductive material comprises a cyclical deposition process, such as an atomic layer deposition (ALD) process. In some embodiments, the substrate is only exposed to temperature of 400° C. or less during formation of the first conductive layer. In some embodiments, the first conductive material film comprises a metal nitride, such as a transition metal nitride. In some embodiments, the first conductive material film comprises one or more of titanium nitride, tantalum nitride, or vanadium nitride. In some embodiments, the first conductive material film has a thickness between about 10 nm to about 30 nm, or between about 13 nm to about 25 nm, or between about 15 nm to about 20 nm.

In some embodiments, the dielectric material film is formed directly on a conductive material, such as the first conductive material film. In some embodiments, forming the dielectric material comprises a cyclical deposition process, such as an atomic layer deposition (ALD) process. In some embodiments, the substrate is only exposed to temperature of 400° C. or less during formation of the dielectric material film. In some embodiments, the dielectric material film has a thickness of less than 100 Angstroms, or less than 70 Angstroms, or less than 60 Angstroms, or between about 30 and about 70 Angstroms, or between 40 Angstroms and 60 Angstroms. In some embodiments, the dielectric material has a dielectric constant greater than 10, or between about 12 and 60. In some embodiments, the dielectric material film comprises a perovskite. In some embodiments, the dielectric material film comprises a metal oxide, such as a group 4 to group 7 metal oxide. In some embodiments, the dielectric material film comprises one or more of hafnium, zirconium, or niobium. In some embodiments, the dielectric material film comprises Hf₍₁₋ₓ₎Zr₍ₓ₎O₂, where x is a number between 0 and 1, or between about 0.25 and about 0.75, or between about 0.4 and 0.6. In some embodiments, forming the dielectric material film comprises doping the dielectric material film. In some embodiments, the dielectric material comprises one or more of hafnium oxide and zirconium oxide doped with one or more of zirconium, hafnium, tantalum, niobium, cerium, silicon, aluminum, germanium, and lanthanum. In some embodiments, the dielectric material film is amorphous as formed.

In some embodiments, the second conductive material film is formed directly on the dielectric material film. In some embodiments, forming a second conductive material comprises a physical vapor deposition (PVD) process. In other embodiments, forming a second conductive material comprises a cyclical deposition process, such as an atomic layer deposition (ALD) process. In some embodiments, the substrate is only exposed to temperature of 400° C. or less during formation of the second conductive layer. In some embodiments, the second conductive material film comprises a metal nitride, such as a transition metal nitride. In some embodiments, the second conductive material film comprises one or more of titanium nitride, tantalum nitride, or vanadium nitride. In some embodiments, the second conductive material film has a thickness between about 13 nm to about 35 nm, between about 15 nm to about 25 nm, or between about 17 nm to about 23 nm.

In some embodiments, the microwave treatment comprises exposing the substrate to microwave radiation. In some embodiments, a duration of the microwave treatment is between about 1 minute and about 60 minutes, or between about 3 minutes and 30 minutes, or between about 5 minutes and about 15 minutes. In some embodiments, during the microwave treatment, an environment of the reaction space comprises one or more of nitrogen (N₂), hydrogen (H₂), ammonia, or an inert gas. In some embodiments, exposing the substrate to the microwave treatment increases a crystallinity of the dielectric material film. In some embodiments, the microwave treatment anneals the dielectric material film.

In some embodiments, the substrate is not exposed to an environment with a temperature above 400° C. during the method.

In accordance with further examples of the disclosure, a device is formed using a method and/or include a structure as described herein.

In accordance with yet further exemplary embodiments of the disclosure, a system is provided for performing a method and/or for forming a structure as described herein.

In accordance with various embodiments of the disclosure, a method of forming a MIM capacitor is provide, the method including: providing a substrate including a first conductive material film on a surface of the substrate; forming a dielectric material film directly on the first conductive material film, wherein a thickness of the dielectric material film is less than 100 Angstroms; forming a second conductive material film directly on the dielectric material film; and after forming the second conductive material film, exposing the substrate to a microwave treatment in a reaction space, wherein a temperature of the reaction space during the microwave treatment is between 325° C. and 400° C.

In some embodiments, the thickness of the dielectric material film is between 30 and 70 Angstroms.

In some embodiments, the dielectric material film includes a perovskite.

In some embodiments, the dielectric material film includes a metal oxide.

In some embodiments, the dielectric material film includes Hf₍₁₋ₓ₎Zr₍ₓ₎O₂, where x is a number between 0 and 1.

In some embodiments, the first conductive material film is formed by a physical vapor deposition process.

In some embodiments, forming the second conductive material film includes a physical vapor deposition process.

In some embodiments, the first conductive material film includes a metal nitride.

In some embodiments, the dielectric material film includes a general formula of MₓD_{y}O_{z}, wherein M includes one or more of hafnium or zirconium, wherein D includes zirconium, hafnium, tantalum, niobium, cerium, silicon, aluminum, germanium, or lanthanum, wherein O is oxygen, wherein x is between 0.8 and 1.2, wherein y is between about 0.005 to 0.05, and wherein z is between about 1.8 to about 2.2.

In some embodiments, the second conductive material film includes a metal nitride.

In some embodiments, the second conductive material film includes titanium nitride.

In some embodiments, a duration of the microwave treatment is between 1 minute and 60 minutes.

In some embodiments, the duration of the microwave treatment is between 5 minutes and 30 minutes.

In some embodiments, exposing the substrate to the microwave treatment increases a crystallinity of the dielectric material film.

In some embodiments, during the microwave treatment, an environment of the reaction space includes one or more of nitrogen (N₂), hydrogen (H₂), ammonia, or an inert gas.

In some embodiments, forming the dielectric material film includes an atomic layer deposition (ALD) process.

In some embodiments, forming the dielectric material film and exposing the substrate to the microwave treatment take place in different reaction spaces.

In some embodiments, the substrate is not exposed to an environment with a temperature above 400° C. during the method.

In some embodiments, a method of forming a MIM capacitor is provided including: providing a substrate including a surface; forming a first conductive material film on the surface by a physical vapor deposition process, wherein the first conductive material film includes titanium nitride; forming a dielectric material film directly on the first conductive material film, wherein the dielectric material film includes Hf₍₁₋ₓ₎Zr₍ₓ₎O₂, wherein 0≤x≤1, and wherein a thickness of the dielectric material film is between 30 Angstroms and 70 Angstroms; forming a second conductive material film directly on the dielectric material film by a physical vapor deposition process, wherein the first conductive material film includes titanium nitride; and after depositing the second conductive material film, exposing the substrate to a microwave treatment in a reaction space, wherein a temperature of the reaction space during the microwave treatment is between 350° C. than 400° C.

In some embodiments, a reactor system is provided including a first reaction chamber; a second reaction chamber including a microwave radiation source; a controller configured to perform the methods disclosed herein; and a vacuum source.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

FIG. 1 illustrates a method for forming a MIM capacitor in accordance with one or more embodiments of the disclosure;

FIG. 2 illustrates an example of a substrate processing apparatus in accordance with one or more examples of the disclosure;

FIG. 3 illustrates an example of a structure that forms part of a device in accordance with one or more examples of the disclosure;

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the plural forms as well, unless the context indicates otherwise.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “structure” can refer to a partially or completely fabricated device structure. By way of examples, a structure can be a substrate or include a substrate with one or more layers and/or features formed thereon.

As used herein, the term “overlying” can refer to two films in direct contact with each other.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

In some embodiments, the term “conductive material” or “conductive material film” can refer to a material with an electrical resistivity less than 300 μΩcm, or less than 100 μΩcm, or less than 30 μΩcm.

In some embodiments, the term “dielectric” or “dielectric material” can refer to a material with a dielectric constant greater than 1, or greater than 2, or greater than 3.9, or greater than 10.

In some embodiments, “metal-insulator-metal capacitor” or “MIM capacitor” can refer to a structure with a dielectric material disposed between a first conductive material and a second conductive material.

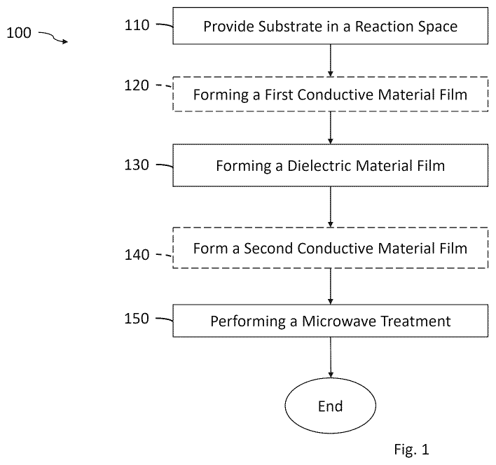

FIG. 1 illustrates a method 100 for forming a MIM capacitor including forming and microwave annealing a dielectric material film in accordance with exemplary embodiments of the disclosure.

Method 100 includes the step of providing a substrate within a reaction space of a reaction chamber (step 110), optionally forming a first conductive material film (step 120), forming a dielectric material film (step 130), optionally forming a first conductive material film (step 140), and performing a microwave treatment on the substrate (step 150).

During step 110, the substrate can be brought to a desired temperature and/or the reaction space can be brought to a desired pressure, such as a temperature and/or pressure suitable for subsequent steps. By way of examples, a temperature (e.g., of a substrate, a substrate support, or an environment) within a reaction space can be between about 0° C. and about 400° C. By way of examples, a pressure within a reaction space can be less than 760 torr, or between about 1 torr and 500 torr.

During step 110, a substrate is provided into a reaction space in a reaction chamber. In accordance with examples of the disclosure, the reaction chamber can form part of a physical vapor deposition chamber (PVD) reactor or a chemical vapor deposition reactor, such as a chemical vapor deposition (CVD) reactor, an atomic layer deposition (ALD) reactor, or the like. Various steps of methods described herein can be performed within a single reaction chamber or can be performed in multiple reaction chambers, such as reaction chambers of a cluster tool.

In some embodiments, the surface of the substrate comprises a conductive material. In some embodiments, the surface of the substrate comprises a conductive material formed by a physical vapor deposition process. In some embodiments, the conductive material one or more of a metal nitride, such as a transition metal nitride. By way of examples, the conductive material can be or include one or more of titanium nitride, tantalum nitride, or vanadium nitride. In some embodiments, the conductive material has a thickness between about 10 nm to about 30 nm, or between about 13 nm to about 25 nm, or between about 15 nm to about 20 nm.

If the substrate does not include a conductive material, the method 100 optionally includes depositing a first conductive material film on the substrate. The first conductive material film may be deposited by any suitable method. In some embodiments, the substrate is only exposed to temperature of 400° C. or less during formation of the first conductive layer. In some embodiments, forming a first conductive material comprises a physical vapor deposition (PVD) process. In embodiments comprising a PVD process, the temperature of the reaction chamber during the PVD process is between 0 and 100° C. In other embodiments, forming a first conductive material comprises a cyclical deposition process, such as an atomic layer deposition (ALD) process. In embodiments comprising a cyclical deposition process, the temperature of the reaction chamber during the cyclical deposition process is between about 300 and 400° C. In some embodiments, the first conductive material film comprises a metal nitride. In some embodiments, the first conductive material film comprises one or more of titanium nitride, tantalum nitride, or vanadium nitride. In some embodiments, the first conductive material film comprises multiple layers, such as barrier layers or laminate layers. In some embodiments, the first conductive material film has a thickness between about 10 nm to about 30 nm, or between about 13 nm to about 25 nm, or between about 15 nm to about 20 nm.

The method 100 continues with forming a dielectric material film (step 130). During step 130, the substrate can be brought to a desired temperature and/or the reaction space can be brought to a desired pressure. By way of examples, a temperature (e.g., of a substrate or a substrate support) within a reaction space can be between about 300° C. and about 400° C., or between about 330° C. and about 380° C. In some embodiments, the substrate is only exposed to temperature of 400° C. or less during formation of the dielectric material film. A pressure within the reaction chamber can also be controlled. By way of examples, a pressure within a reaction space can be less than 760 torr, or between about 1 torr and 100 torr. In some embodiments, the dielectric material film is formed directly on the first conductive material. In some embodiments, forming the dielectric material film comprises a cyclical deposition process, such as an atomic layer deposition (ALD) process or a cyclical CVD process. In some embodiments, forming the dielectric material film comprises doping the dielectric material film. Doping the dielectric material film can be accomplished by any suitable process method. In some embodiments, the dielectric material film is doped according to a method disclosed in U.S. patent application Ser. No. 18/319,933, the entirety of which is incorporated by reference herein. In some embodiments, forming the dielectric material is a thermal deposition process—e.g., no plasma or other excitation source is used to form excited species of a precursor or reactant.

In some embodiments, the dielectric material film has a thickness of less than 100 Angstroms, or between about 30 and about 70 Angstroms. In some embodiments, the dielectric material has a dielectric constant greater than 10, or greater than 20, between about 20 and 35. In some embodiments, the dielectric material film is amorphous as formed. In some embodiments, the dielectric material film comprises a perovskite. In some embodiments, the dielectric material film comprises a metal oxide. In some embodiments, the dielectric material film comprises one or more group 4 to group 7 metals. By way of examples, the dielectric material film can include one or more of hafnium, zirconium, tantalum, niobium, or the like. By way of particular example, the dielectric material film comprises Hf₍₁₋ₓ₎Zr₍ₓ₎O₂, where x is a number between 0 and 1, or between about 0.25 and about 0.75, or between about 0.5 to about 0.75, or between about 0.45 to 0.55. In some embodiments, the dielectric material film comprises a doped dielectric material film, with the dopant comprising one or more of zirconium, hafnium, tantalum, niobium, cerium, silicon, aluminum, germanium, and lanthanum. In some embodiments, the doped dielectric material film comprises one or more of a hafnium oxide and a zirconium oxide or a hafnium zirconium oxide. In some embodiments, the doped dielectric film comprises a general formula of MₓD_{y}O_{z}, where M is the metal, D is the dopant, and O is oxygen, where x is between 0.8 and 1.2 or between about 0.9 and 1.1, y is between about 0.005 to 0.5 or between about 0.01 and 0.2, or between about 0.01 and 0.05, and z is between about 1.8 to about 2.2 or 1.9 and 2.1. In some embodiments, M comprises one or more of hafnium or zirconium, or a combination of hafnium and zirconium. In some embodiments, M comprises a combination of hafnium and zirconium with a ratio of about 1:3 to about 1:1 of hafnium to zirconium. In some embodiments, D is one or more of zirconium, hafnium, tantalum, niobium, cerium, silicon, aluminum, germanium, and lanthanum.

Not to be bound by theory, the use of tantalum or niobium doping in a hafnium oxide or a hafnium zirconium oxide reduces oxygen vacancy concentration and leakage current. In some embodiments, a leakage current of the dielectric film is reduced by greater than 80%, or greater 98% by doping with tantalum or niobium. In some embodiments of a hafnium zirconium oxide with a ratio of hafnium to zirconium in a range of about 1:2 to about 1:4, doping with about 0.5% to 50 at % dopant, or between 1 and 20 at % dopant, or between 1 and 5 at % dopant of tantalum or niobium increases the dielectric constant by greater than about 5%, or between about 7% and about 10%. In some embodiments of a hafnium zirconium oxide with a ratio of hafnium to zirconium in a range of about 1:1.2 to about 1.2:1, doping with about 1 to 5 at % of tantalum or niobium increases the dielectric constant by greater than about 10%.

In some embodiments, the dielectric material film comprises a first liner layer disposed on the bottom of the dielectric material film. In some embodiments, the dielectric material film comprises a second liner layer disposed on the bottom of the dielectric material film. In some embodiments, the first liner layer and/or the second liner layer has a thickness of between about 3 Angstroms and 10 Angstroms, or between about 4 and 6 Angstroms. In some embodiments, the first liner layer and/or second liner layer comprises a metal oxide. In some embodiments, the first liner layer and/or second liner layer comprises a metal oxide different than bulk of the dielectric material film. In some embodiments, the first liner layer and/or second liner layer comprises a hafnium oxide, an aluminum oxide, a niobium oxide, or a titanium oxide.

The method 100 continues, optionally, with depositing a second conductive material film on the substrate 140. During step 140, the substrate can be brought to a desired temperature and/or the reaction space can be brought to a desired pressure. By way of examples, a temperature (e.g., of a substrate or a substrate support) within a reaction space can be less than about 400° C. In some embodiments, the substrate is only exposed to temperature of 400° C. or less during formation of the dielectric material film. By way of examples, a pressure within a reaction space can be less than 760 torr, or between about 1 torr and 100 torr. In some embodiments, the second conductive material is formed directly on the dielectric material film. In some embodiments, forming a second conductive material comprises a physical vapor deposition (PVD) process. In embodiments comprising a PVD process, the temperature of the reaction chamber during the PVD process is between 0 and 100° C. In other embodiments, forming a second conductive material comprises a cyclical deposition process, such as an atomic layer deposition (ALD) process. In embodiments comprising a cyclical deposition process, the temperature of the reaction chamber during the cyclical deposition process is between about 300 and 400° C. In some embodiments, the second conductive material film comprises a metal nitride, such as a transition metal nitride. In some embodiments, the second conductive material film comprises one or more of titanium nitride, tantalum nitride, or vanadium nitride. In some embodiments, the second conductive material film comprises the same material as the first conductive material film. In some embodiments, the second conductive material film comprises a different material as the first conductive material film. In some embodiments, the first conductive material film comprises multiple layers, such as layers that can form a laminate. In some embodiments, the second conductive material film has a thickness between about 13 nm to about 35 nm, between about 15 nm to about 25 nm, or between about 17 nm to about 23 nm.

The method 100 continues with performing a microwave treatment (step 150). During step 150, the substrate can be brought to a desired temperature and/or the reaction space can be brought to a desired pressure. In some embodiments, during the microwave treatment, an environment of the reaction space comprises a nitrogen and/or hydrogen containing gas, such as one or more of nitrogen (N₂), hydrogen (H₂), ammonia, and/or an inert gas. In some embodiments, a temperature of the reaction space during the microwave treatment is less than about 400° C., or between 325° C. and 350° C., or between about 350° C. than 400° C. By way of examples, a pressure within a reaction space can be between about 0.8 atm and 1.2 atm. In some embodiments, the microwave treatment comprises exposing the substrate to microwave radiation. In some embodiments, a duration of the microwave treatment is between about 1 minute and about 60 minutes, or between about 3 minutes and 30 minutes, or between about 5 minutes and about 15 minutes. In some embodiments, a microwave power during the microwave treatment is between about 1kW to 100 kW, or between 2 kW and 6 kW. A frequency of microwave radiation during step 150 can be between about 300 MHz and about 300 GHz, or between about 2 GHz to about 8 GHz. In some embodiments, exposing the substrate to the microwave treatment increases a crystallinity of the dielectric material film. In some embodiments, exposing the substrate to the microwave treatment increases the dielectric constant of the dielectric material film.

In some embodiments, the microwave treatment (step 150) is performed after forming the second conductive material film (step 140). In some embodiments, the microwave treatment (step 150) is additionally or alternatively performed before forming the second conductive material film (step 140).

Various steps of methods described herein can be performed within a single reaction chamber or can be performed in multiple reaction chambers, such as reaction chambers of a cluster tool. In some embodiments, the method 100 may take place in a single reaction space. In some embodiments, one or more substeps of method 100 may take place in a different reaction space or a different reaction chamber.

Additionally, a carrier and/or inert gas can be co-flowed throughout method 100 or during any of the sub-steps of method 100. By way of example, a carrier and/or an inert gas can be one or more of helium, argon, or nitrogen.

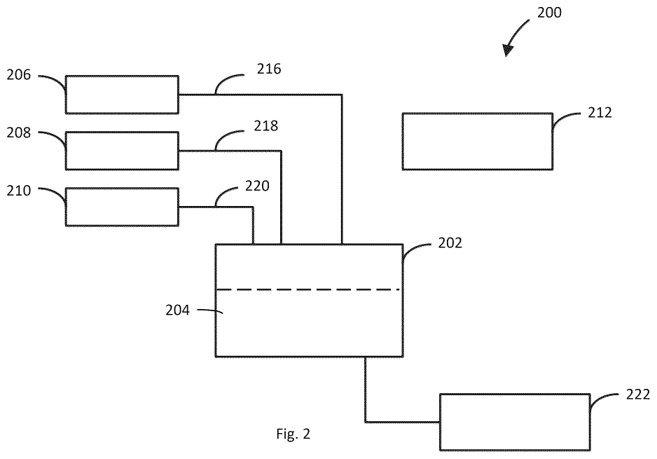

FIG. 2 illustrates an example of a substrate processing apparatus 200 in accordance with one or more examples of the disclosure. Apparatus 200 can be used to perform a method as described herein and/or form a structure or device portion as described herein.

In the illustrated example, apparatus 200 includes one or more reaction chambers 202, a reaction space 204, one or more precursor gas sources 206, an inert gas source 208, a microwave radiation source 210, an exhaust source 222, and a controller 212.

Reaction chamber 202 can include any suitable reaction chamber, such as a physical vapor deposition (PVD), atomic layer deposition (ALD) or chemical vapor deposition (CVD) reaction chamber.

One or more precursor gas sources 206 can include one or more vessels and one or more precursors/reactants that may be used to form conductive layers or dielectric material films as described herein-alone or mixed with one or more carrier (e.g., inert) gases. Inert gas source 208 can include a vessel and one or more inert gases, such as nitrogen, argon, or helium. Although illustrated with two gas sources 206, 208, apparatus 200 can include any suitable number of gas sources. Gas sources 206 and 208 can be coupled to reaction chamber 202 via lines 216-218, which can each include flow controllers, valves, heaters, and the like.

Microwave radiation source 210 can include a microwave generator to generate microwave radiation in the reaction space 204 of the reaction chamber 202.

Exhaust source 222 can include one or more vacuum pumps.

Controller 212 includes electronic circuitry and software to selectively operate valves, manifolds, heaters, pumps, and other components included in the apparatus 200. Such circuitry and components operate to introduce precursors, reactants, and gases from the respective sources 206-208. Controller 212 can control timing of gas pulse sequences, temperature of the substrate and/or reaction chamber, pressure within the reaction chamber, and various other operations to provide proper operation of the apparatus 200. Controller 212 can include control software to electrically or pneumatically control valves to control flow of precursors, reactants, and purge gases into and out of the reaction chamber 202. Controller 212 can include modules such as a software or hardware component, e.g., a FPGA or ASIC, which performs certain tasks. A module can advantageously be configured to reside on the addressable storage medium of the control system and be configured to execute one or more processes or methods, as described herein.

Other configurations of apparatus 200 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 202 and/or reaction space 204. Further, as a schematic representation of a system, many components have been omitted for simplicity of illustration, and such components may include, for example, various valves, manifolds, purifiers, heaters, containers, vents, and/or bypasses.

During operation of apparatus 200, substrates, such as semiconductor wafers (not illustrated), are transferred from, e.g., a substrate handling system to reaction chamber 202. Once substrate(s) are transferred to reaction chamber 202, one or more gases from gas sources 206-208, such as precursors, reactants, carrier gases, and/or purge gases, are introduced into reaction chamber 202.

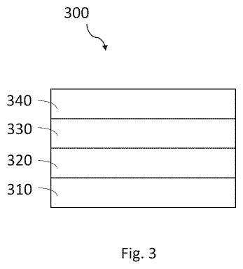

FIG. 3 illustrates a structure/a portion of a device 300 in accordance with additional examples of the disclosure. Device or structure 300 includes a substrate 310, a film comprising a first conductive material 320, a film comprising a dielectric material 330, and a film comprising a second conductive material 340. In some embodiments, device or structure 300 is at least part of a MIM capacitor. The first conductive material film 320 may be formed by a method described in this disclosure. In some embodiments, the first conductive material film 320 comprises a metal nitride, such as titanium nitride. The first conductive material film 320 may have a thickness between about 10 nm to about 30 nm, or between about 13 nm to about 25 nm, or between about 15 nm to about 20 nm. The dielectric material film 330 may be formed by a method described in this disclosure. In some embodiments, the dielectric material film 330 is a hafnium oxide or zirconium oxide, or a hafnium zirconium oxide. In some embodiments, the dielectric material film 330 is a doped dielectric material film. In some embodiments, the doped dielectric material film comprises one or more of a hafnium oxide and a zirconium oxide or a hafnium zirconium oxide. In some embodiments, the doped dielectric film comprises a general formula of MₓD_{y}O_{z}, where M is the metal, D is the dopant, and O is oxygen, where x is between 0.8 and 1.2, y is between about 0.005 to 0.05 or between about 0.01 and 0.03, and z is between about 1.8 to about 2.2. In some embodiments, M comprises one or more of hafnium or zirconium, or a combination of hafnium and zirconium. In some embodiments, M comprises a combination of hafnium and zirconium with a ratio of about 1:3 to about 1:1 of hafnium to zirconium. In some embodiments, D is one or more of zirconium, hafnium, tantalum, niobium, cerium, silicon, aluminum, germanium, and lanthanum. In some embodiments, the dielectric material film has a thickness of less than 100 Angstroms, or between about 30 and about 70 Angstroms, or between about 40 Angstroms and about 60 Angstroms. In some embodiments, the dielectric material film has a dielectric constant greater than 10, or greater than 20, between about 20 and 35. In some embodiments, the dielectric material film comprises a perovskite. The second conductive material film 340 may be formed by a method described in this disclosure. In some embodiments, the second conductive material film 340 comprises a metal nitride, such as titanium nitride. The second conductive material film 340 may have a thickness between about 13 nm to about 35 nm, or between about 15 nm to about 25 nm, or between about 17 nm to about 23 nm.

In some embodiments, the film comprising a second conductive material 340 is overlying the film comprising a dielectric material 330, and the film comprising dielectric material 330 is overlying the film comprising a first conductive material 320.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a MIM capacitor, the method comprising:
providing a substrate comprising a first conductive material film on a surface of the substrate;
forming a dielectric material film directly on the first conductive material film, wherein a thickness of the dielectric material film is less than 100 Angstroms;
forming a second conductive material film directly on the dielectric material film; and
after forming the second conductive material film, exposing the substrate to a microwave treatment in a reaction space,
wherein a temperature of the reaction space during the microwave treatment is between 325° C. than 400° C.

2. The method of claim 1, wherein the thickness of the dielectric material film is between 30 and 70 Angstroms.

3. The method of claim 1, wherein the dielectric material film comprises a perovskite.

4. The method of claim 1, wherein the dielectric material film comprises a metal oxide.

5. The method of claim 1, wherein the dielectric material film comprises Hf₍₁₋ₓ₎Zr₍ₓ₎O₂, where x is a number between 0 and 1.

6. The method of claim 1, wherein the first conductive material film is formed by a physical vapor deposition process.

7. The method of claim 1, wherein forming the second conductive material film comprises a physical vapor deposition process.

8. The method of claim 1, wherein the first conductive material film comprises a metal nitride.

9. The method of claim 1, where the dielectric material film comprises a general formula of MₓD_{y}O_{z}, wherein M comprises one or more of hafnium or zirconium, wherein D comprises zirconium, hafnium, tantalum, niobium, cerium, silicon, aluminum, germanium, or lanthanum, wherein O is oxygen, wherein x is between 0.8 and 1.2, wherein y is between 0.005 to 0.05, and wherein z is between 1.8 to 2.2.

10. The method of claim 1, wherein the second conductive material film comprises a metal nitride.

11. The method of claim 10, wherein the second conductive material film comprises titanium nitride.

12. The method of claim 1, wherein a duration of the microwave treatment is between 1 minute and 60 minutes.

13. The method of claim 12, wherein the duration of the microwave treatment is between 5 minutes and 30 minutes.

14. The method of claim 1, wherein exposing the substrate to the microwave treatment increases a crystallinity of the dielectric material film.

15. The method of claim 1, wherein during the microwave treatment, an environment of the reaction space comprises one or more of nitrogen (N₂), hydrogen (H₂), ammonia, or an inert gas.

16. The method of claim 1, wherein forming the dielectric material film comprises an atomic layer deposition (ALD) process.

17. The method of claim 1, wherein forming the dielectric material film and exposing the substrate to the microwave treatment take place in different reaction spaces.

18. The method of claim 1, wherein the substrate is not exposed to an environment with a temperature above 400° C. during the method.

19. A method of forming a MIM capacitor, the method comprising:
providing a substrate comprising a surface;
forming a first conductive material film on the surface by a physical vapor deposition process, wherein the first conductive material film comprises titanium nitride;
forming a dielectric material film directly on the first conductive material film, wherein the dielectric material film comprises Hf₍₁₋ₓ₎Zr₍ₓ₎O₂, wherein 0≤x≤1, and wherein a thickness of the dielectric material film is between 30 Angstroms and 70 Angstroms;
forming a second conductive material film directly on the dielectric material film by a physical vapor deposition process, wherein the first conductive material film comprises titanium nitride; and
after depositing the second conductive material film, exposing the substrate to a microwave treatment in a reaction space,
wherein a temperature of the reaction space during the microwave treatment is between 350° C. than 400° C.

20. A reactor system comprising:
a first reaction chamber;
a second reaction chamber comprising a microwave radiation source;
a controller configured to perform the method of claim 1; and
a vacuum source.
